(19) United States
(12) Patent Application Publication
(10) Pub. No.: US 2026/0173649 A1
(43) Pub. Date: Jun. 18, 2026

(54) ORGANIC ELECTROLUMINESCENT DEVICES

(71) Applicant: Universal Display Corporation, Ewing, NJ (US)

(72) Inventors: Haridas Mundoor, Ewing, NJ (US); Nicholas J. Thompson, New Hope, PA (US)

(21) Appl. No.: 19/408,837

(22) Filed: Dec. 4, 2025

Related U.S. Application Data
(60) Provisional application No. 63/733,558, filed on Dec. 13, 2024.

(51) Int. Cl. H10K 50/858; G02B 5/00; H10K 50/854

(52) U.S. Cl. CPC H10K 50/858; G02B 5/008; H10K 50/854

(57) ABSTRACT

Organic electroluminescent devices are provided, including devices having an emissive layer in addition to an outcoupling layer with material having an emissive state. The material having an emissive state within the outcoupling layer converts the energy confined in the multipolar localized surface plasmon resonance modes to dipolar emissive modes, thereby increasing the light outcoupling efficiency of devices.

### CROSS-REFERENCE TO RELATED APPLICATIONS

This application claims priority to U.S. Patent Application Ser. No. 63/733,558, filed Dec. 13, 2024, the entire contents of which are incorporated herein by reference.

### FIELD

The present invention relates to emissive devices including organic emissive devices with an outcoupling layer, and techniques for fabricating the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent molecules capable of phosphorescent emission is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; a “yellow” layer, material, region, or device refers to one that has an emission spectrum with a peak wavelength in the range of about 540-600 nm; a “cyan” layer, material, or device refers to one that emits or has an emission spectrum with a peak wavelength in the range of about 490-520 nm; and an “orange” layer, material, or device refers to one that emits or has an emission spectrum with a peak wavelength in the range of about 570-620 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” or “dark blue” component has a peak emission wavelength in the range of about 400-470 nm, though these ranges may vary for some configurations. A “light green” component has a peak emission wavelength in the range of about 520-560 nm, and a “deep green” or “dark green” component has a peak emission wavelength in the range of about 500-520 nm, though these ranges may vary for some configurations. A near infrared (“NIR”) component has a peak emission wavelength in the range of about 700-1800 nm. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon the spectrum of light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and cathode. According to an embodiment, the organic light emitting device is incorporated into one or more devices selected from a consumer product, an electronic component module, and/or a lighting panel.

An organic emissive device is provided which includes a substrate; a first electrode; an emissive layer including an organic emissive material disposed over the first electrode; a second electrode disposed over the emissive layer; and an outcoupling layer disposed over the second electrode, wherein the outcoupling layer comprises a material having an emissive state.

In some embodiments, within the organic emissive device may be an enhancement layer. The enhancement layer may replace one of the electrodes within the organic emissive device or may be in addition to the electrodes. In other words, the first electrode may be the enhancement layer, the second electrode may be the enhancement layer, and/or the organic device may include an additional enhancement layer. The enhancement layer may be disposed below the outcoupling layer. In an embodiment, the enhancement layer that is separate from the second electrode may be disposed between the emissive layer and the second electrode or may be disposed above the second electrode. When the enhancement layer is disposed above the second electrode, the enhancement layer may be disposed directly on top of the second electrode. The second electrode may be an optically transparent material, a metal material, or a non-metallic material and selection thereof may be based upon whether the organic emissive device is a plasmonic organic emissive device or not. It should be noted that a non-metallic electrode may be an electrode made of materials that include non-metallic materials. In other words, a non-metallic electrode is an electrode that is not purely metallic. Thus, an electrode that includes solely non-metallic materials or that includes both non-metallic and metallic materials would be considered a non-metallic electrode.

The enhancement layer, regardless of whether it is the second electrode or a separate layer, may include a plasmonic material exhibiting surface plasmon resonance that non-radiatively couples to the organic emissive material of the emissive layer and transfers excited state energy from the organic emissive material to non-radiative mode of surface plasmon polaritons. The enhancement layer may be provided no more than a threshold distance away from the organic emissive material. The organic emissive material may have a total non-radiative decay rate constant and a total radiative decay rate constant due to the presence of the enhancement layer. The threshold distance may be a distance where the total non-radiative decay rate constant is equal to the total radiative decay rate constant, as disclosed in U.S. Pat. No. 9,960,386, and incorporated by reference in its entirety. The organic emissive material may have a total non-radiative decay constant

$${k}_{non - rad}^{0} ,$$

a total non-radiative decay rate constant

$${k}_{rad}^{0} ,$$

a total non-radiative decay rate constant due to the enhancement layer

$${k}_{non - rad}^{plasmon} ,$$

and a total radiative decay rate constant due to the enhancement layer

$${k}_{r a d}^{plasmon} .$$

The threshold distance may be a distance at which

$$\frac{{k}_{rad}^{plasmon}}{{k}_{non - rad}^{plasmon}} = \frac{{k}_{rad}^{0}}{{k}_{non - rad}^{0}} .$$

The enhancement layer described above may comprise a plasmonic material exhibiting surface plasmon resonance that non-radiatively couples to the emitter material. In some embodiments, the emitter may couple to the surface plasmon modes through a nearfield interaction. In some other embodiments, the emitter may couple to the surface plasmon mode through a far-field optical interaction. The process of coupling between emitter and surface plasmon may enable transfer of excited state energy from the emitter material to non-radiative and/or radiative modes of surface plasmon polariton.

The entirety of the outcoupling layer may be the material having an emissive state or only a portion of the outcoupling layer may include the material having an emissive state. The outcoupling layer may include a dielectric material that is doped with the material having an emissive state. The dielectric material may have a refractive index of greater than 1.5, greater than 1.8, greater than 2, or greater than 2.5. In an embodiment, the material having an emissive state may have a specific volume of the dielectric material and the material having an emissive state combined may be less than 25%, less than 15%, less than 10%, less than 5%, less than 3%, less than 1%, less than 0.5%, or less than 0.1%. The outcoupling layer may comprise a porous material where the material having an emissive state is embedded within the porous material. It should be noted that the porous material may also have regions of other materials that are not the material having an emissive state. The porous material may comprise a metal organic framework (MOF) or a covalent organic framework (COF).

The outcoupling layer may include a dielectric spacer that is disposed over the second electrode. The thickness of the dielectric spacer may be less than 50 nm, less than 30 nm, less than 20 nm, less than 2 nm, or 0 nm. The outcoupling layer may include nanoparticles. The nanoparticles may be metal nanoparticles or dielectric nanoparticles. The dielectric nanoparticles may be doped with the material having an emissive state. The metal nanoparticles may be a part of a metal layer that is disposed above the second electrode, with the metal nanoparticles and the metal layer being a single continuous metal layer. In an embodiment, the metal nanoparticles may be one or more structures patterned on top of the metal layer. In an alternative embodiment, the metal nanoparticles may be part of a single continuous metal layer. The single continuous metal layer may include recessions between the metal nanoparticles where the material having an emissive state is deposited within the recessions.

The nanoparticles, either metal nanoparticles or dielectric nanoparticles, may be disposed over the material having an emissive state. The material having an emissive state may be located above the nanoparticles, below the nanoparticles, and/or between the nanoparticles. The nanoparticles may be encased in a shell doped with the material having an emissive state. There may be a material that is located between the nanoparticles encased in a shell. This material may be a dielectric material, air, and/or the like. The material having an emissive state may be located between the nanoparticles and may be quantum dots, dielectric material that is doped with the material having an emissive state, and/or the like. The nanoparticles may be different shapes, for example, a sphere, a cube, a square prism, a cylinder, a rectangular prism, a rod, a spheroid, an irregular shape, and/or the like. The different shapes may allow for nanoparticles having a dielectric core doped with the material having an emissive state and having a metal shell, nanoparticles of a dielectric material doped with the material having an emissive state and having a metallic layer located within the dielectric material, and/or the like.

The device may be or may be a part of a consumer electronic device, which may be at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3A-3F show a schematic representation of plasmonic OLEDs utilizing a material having an emissive state for light outcoupling. FIG. 3A illustrates a device design using the material having an emissive state dispersed in a dielectric layer above the second electrode which serves as the enhancement layer. FIG. 3B illustrates a device design using the material having an emissive state dispersed in a dielectric layer above the enhancement layer for a device using a separate second electrode deposited below the enhancement layer. FIG. 3C illustrates a device design using a nanoparticle outcoupling layer and material having an emissive state for light outcoupling. The material having an emissive state is dispersed in a dielectric layer above the second electrode. FIG. 3D illustrates the device design using nanoparticle outcoupling layer and material having an emissive state for light outcoupling for devices using separate enhancement layer and second electrode. The material having an emissive state being dispersed in a dielectric layer above the enhancement layer. FIG. 3E illustrates the device design using the material having an emissive state dispersed in a dielectric layer with the nanoparticles within the dielectric layer. FIG. 3F illustrates the material having an emissive state as a shell around the nanoparticles.

FIG. 4A-4C show a schematic representation of plasmonic OLEDs with a periodic array of nanoparticles and the material having an emissive state for light outcoupling. FIG. 4A illustrates the material having an emissive state being dispersed within a dielectric layer between the second electrode and the nanoparticles. FIG. 4B illustrates the material having an emissive state as a shell around the nanoparticles. FIG. 4C illustrates the material having an emissive state within a dielectric material located between the nanoparticles.

FIG. 5A-5C show a schematic representation of a plasmonic OLED with metal nanoparticles and a material having an emissive state for light outcoupling. FIG. 5A illustrates the device design where the material having an emissive state as quantum dots and being located between the metal nanoparticles. FIG. 5B illustrates a metal layer with the metal nanoparticles as a single continuous layer having recessions between the metal nanoparticles filled with the material having an emissive state as quantum dots. FIG. 5C illustrates the material having an emissive state as transition metal dichalcogenides (TMDs) as a layer beneath the metal nanoparticles.

FIG. 6A-6C show a schematic representation of a plasmonic OLED where the nanoparticles are dielectric nanoparticles. FIG. 6A illustrates the dielectric nanoparticles doped with the material having an emissive state. FIG. 6B illustrates the dielectric nanoparticles with a dielectric material doped with the material having an emissive state being located between the nanoparticles. FIG. 6C illustrates the dielectric nanoparticles with the material having an emissive state as quantum dots and being located between the dielectric nanoparticles.

FIG. 7A-7C show a schematic representation of a OLED with a non-metallic second electrode. FIG. 7A illustrates the material having an emissive state as a quantum dot layer disposed above the second electrode. FIG. 7B illustrates an outcoupling layer including nanoparticles above the second electrode with the material having an emissive state as quantum dots located between the nanoparticles. FIG. 7C illustrates an outcoupling layer including nanoparticles having a material with an emissive state shell. FIG. 7D illustrates an outcoupling layer including nanoparticles doped with the material with an emissive state. FIG. 7E illustrates an outcoupling layer with nanoparticles shaped as spheres having a dielectric core doped with the material having an emissive state and a metal shell. FIG. 7F illustrates an outcoupling layer with nanoparticles shaped as spheres made of a dielectric material doped with the material having an emissive state and a metallic layer located within the sphere.

FIG. 8A-8C depicts the emission spectra of material with an emissive state (dashed line) and emissive material and/or emissive layer comprising the emissive material (dashed line). FIG. 8A illustrates emissive spectra overlapping. FIG. 8B illustrates a partial overlap of emissive spectra. FIG. 8C illustrates no overlap between emissive spectra.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

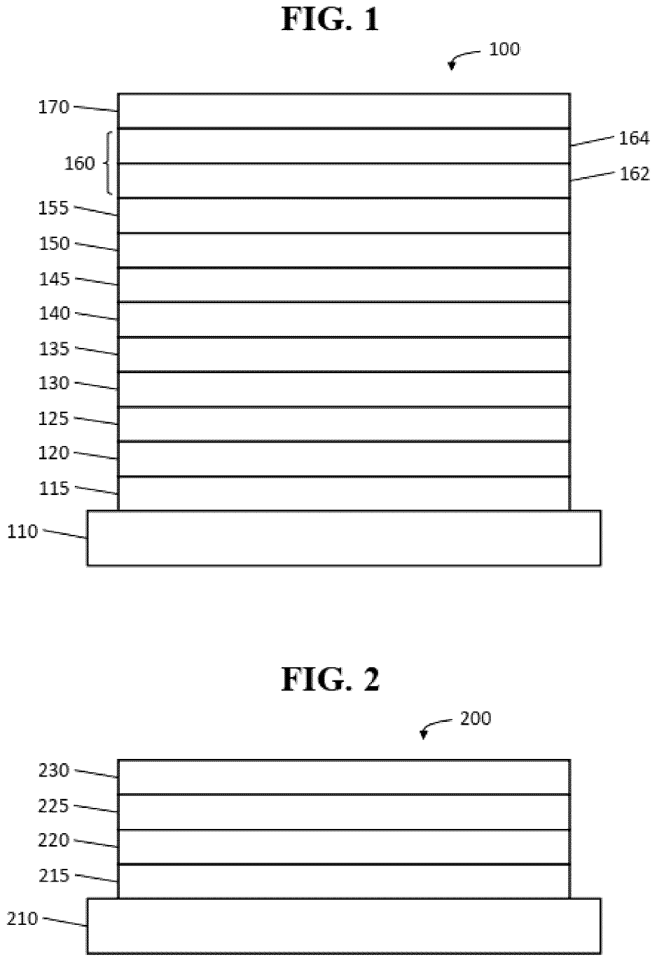

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. The emissive layer may use different emissive display technologies. Such technologies may include inorganic and/or organic devices, such as LEDs, mini LEDs, microLEDs, thin electroluminescent films, organic light emitting devices, and the like. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be placed, disposed, or deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, where the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters or extracts the energy from the surface plasmon polaritons. In some embodiments this energy is scattered or extracted as photons to free space. In other embodiments, the energy is scattered or extracted from the surface plasmon mode into other modes of the device such as but not limited to the organic waveguide mode, the substrate mode, or another waveguiding mode. If energy is scattered or extracted to the non-free space mode of the OLED other outcoupling schemes could be incorporated to extract that energy to free space. In some embodiments, one or more dielectric spacer layers can be disposed between the enhancement layer and the outcoupling layer. The plasmonic stack may include a dielectric spacer material (i.e., a dielectric spacer layer) having a refractive index selected based on a color of light emitted by the organic emissive material. In an embodiment, the dielectric spacer material (i.e., dielectric spacer layer) may be located between the enhancement layer and the nanoparticles in the plasmonic stack. In an alternative embodiment, the dielectric spacer material may be located between the two electrodes in the plasmonic stack. In yet another embodiment, the dielectric spacer material may be located on either side of, but not necessarily adjacent to, either electrode, outside of the plasmonic stack. In yet another embodiment, the dielectric spacer material may be located between the enhancement layer and the outcoupling layer or may be integrated within the outcoupling layer. In some embodiments, the dielectric spacer layer may be found only in a plasmonic stack sub-pixel, only in a non-plasmonic stack sub-pixel or in both. Examples of material suitable for use in dielectric spacer layers include dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles where the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In embodiments of the disclosed subject matter, a device may include an enhancement layer that is disposed over an emissive area of at least one sub-pixel that is configured to have a Lambertian emission and/or at least one sub-pixel having a microcavity configured for direct emission, as described in detail below. In at least some of such embodiments, the enhancement layer may include a plasmonic structure that is disposed a predetermined threshold distance from the emissive area. The predetermined threshold distance may be a distance at which a total non-radiative decay rate constant is equal to a total radiative decay rate constant. In some of such embodiments, device may include an outcoupling layer is disposed over the enhancement layer on the opposite side of the emissive area.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

In some embodiments, a compound in an emissive material and/or layer in an OLED may be used as a phosphorescent sensitizer, where one or multiple layers in the OLED may include an acceptor in the form of one or more fluorescent and/or delayed fluorescence emitters. In some embodiments, the compound can be used as one component of an exciplex to be used as a sensitizer. As a phosphorescent sensitizer, the compound may be capable of energy transfer to the acceptor, and the acceptor may emit the energy or further transfer energy to a final emitter. The acceptor concentrations may range from 0.001% to 100%. The acceptor may be in either the same layer as the phosphorescent sensitizer or in one or more different layers. In some embodiments, the acceptor may be a TADF emitter. In some embodiments, the acceptor may be a fluorescent emitter. In some embodiments, the emission may arise from any or all of the sensitizer, acceptor, and/or final emitter.

On the other hand, E-type delayed fluorescence described above does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, an optical communication device, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer having carbon nanotubes.

In some embodiments, the OLED further comprises a layer having a delayed fluorescent emitter. In some embodiments, the OLED comprises a RGB pixel arrangement or white plus color filter pixel arrangement. In some embodiments, the OLED is a mobile device, a hand-held device, or a wearable device. In some embodiments, the OLED is a display panel having less than 10-inch diagonal or 50 square inch area. In some embodiments, the OLED is a display panel having at least 10-inch diagonal or 50 square inch area. In some embodiments, the OLED is a lighting panel.

In some embodiments of the emissive region, the emissive region further comprises a host.

In some embodiments, the compound causing light to be generated can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes, including phosphor sensitized fluorescence.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Embodiments described herein may be found in devices that have pixels that include one or more sub-pixels. Embodiments described herein may be a device in at least one of the one or more sub-pixels. In a first embodiment, at least one of the sub-pixels may be in a side-by-side (SBS) architecture. In a SBS architecture, at least one or more emissive layers of each sub-pixel in the pixel may be different than another sub-pixel in the pixel. In a SBS architecture, at least one or more outcoupling layers of each sub-pixel may be different than an outcoupling layer of another sub-pixel in the pixel. These differences may lead to different light emission characteristic for each sub-pixel. Generally, a “Red” sub-pixel will have a red emissive layer and the red emissive layer emits red light and the sub-pixel emits red light. In an embodiment, there may be no color filter or color altering layer in a SBS architecture, although this is not a requirement and a color filter or color altering layer may be used. In a second embodiment, at least one of the sub-pixels may be in a stacked architecture. In a stacked architecture, at least one or more emissive layer is shared between two or more sub-pixels in the pixel. Generally, this is used in a white plus color filter/color altering layer architecture, where the emissive layers in the pixel produce “white” light and different color filter/color altering layer arrangements are used for sub-pixels in the pixel to produce a desired color. For example, the stack may produce “white,” a first sub-pixel may have a red color filter/color altering layer, so the first sub-pixel may produce red light and a second sub-pixel may have a green color filter/color altering layer, so the second sub-pixel may produce green light. Any color filtering/altering may be used to produce any color light. Additionally, the stack does not necessarily need to produce a “white” light and can produce any color light. Devices may be made that are a mixture of both SBS and stack architecture to produce pixel/sub-pixel designs that includes some or all of the embodiments described. Embodiments of the present invention may be included in one or more of a SBS or stacked pixel/sub-pixel designs.

Additionally, any of the devices herein may replace either the first electrode or the second with a charge generation layer. Here, a second device (or more), similar or different to the devices to the first device and/or similar or different to devices described in embodiments herein, may be placed in series with the first device in order to form a tandem device. In a tandem device, the first device may have an anode or a cathode on a side of the first device farther from the second device, between the first and second device may be a charge generation layer which replaces the anode or cathode, and the second device may have either an anode or cathode (whichever was not found in the first device) on a side of the of the second device farther from the first device.

The light outcoupling efficiency of plasmonic OLEDs depends on the plasmon to photon conversion efficiency of the outcoupling layer. In plasmonic OLEDs that use metal nanoparticles in the outcoupling layer, the light outcoupling depends on the localized surface plasmon resonance (LSPR) modes induced on the nanoparticles. The dipolar LSPR modes are considered to be more efficient in light outcoupling, while the multipolar LSPR modes often lead to increased optical losses reducing the device efficiency. In the described system, the outcoupling layer is designed to maximize the number of dipolar modes that are used to convert plasmons to photons using an emissive state. In particular, the light outcoupling scheme utilizes a material having an emissive state outside the OLED stack as would typically be defined as the layer between the two electrodes. In other words, in the described system, the OLED stack includes an emissive layer within the stack and also a material having an emissive state in the outcoupling layer which is outside the OLED stack. It should be noted, the emissive state in the outcoupling layer may alternatively, or in addition to (i.e., two emissive states outside the OLED stack), be found in a dielectric layer outside and/or inside the OLED stack. This light outcoupling scheme can replace the conventional nanoparticle based light outcoupling scheme or enhance the light outcoupling for the nanoparticle based light outcoupling scheme by converting the energy confined in the multipolar LSPR modes to dipolar LSPR emissive modes.

The described device includes a substrate, a first electrode, an emissive layer comprising an organic emissive material disposed over the first electrode, and a second electrode within the OLED stack. Additionally, the describe device includes an enhancement layer. In an embodiment, the enhancement layer may be the second electrode or another layer (not shown) disposed above or below the enhancement layer. Additionally, the described device includes an outcoupling layer disposed over the second electrode. The device could include different variations of layers, for example, additional layers, the layers in a different order, and/or the like. Such stacks are described in connection with FIG. 1 and FIG. 2. The described device includes a unique outcoupling layer that includes a material having an emissive state. The material having an emissive state includes any material that could emit light, by the absorption of light, any electromagnetic radiation, and/or when energized by an electric field, such as an OLED. In some devices, the light outcoupling through the material having an emissive state is the dominant mode of light outcoupling. To enable this, the material having an emissive state is deposited above the enhancement layer or dispersed within a dielectric layer above the enhancement layer. In some other devices, the material having an emissive state in the outcoupling layer enhances the light that is emitted by the devices using nanoparticle based light outcoupling, making it brighter, enhancing color saturation, controlling emission line width, controlling emission wavelength/color, controlling angular emission, and/or the like. Having the emitter dispersed in the spacer layer may also help reduce ambient light reflection from the device. In a traditional device where the outcoupling layer does not include a material having an emissive state, the particles on top of the enhancement layer in a plasmonic OLED device couple the light to air. In an OLED device, using non-metallic electrodes (noted as electrodes that include non-metallic material, even if some metallic material is also included) the particles on top of the second electrode, or cathode, may couple the light to air. In the described device, instead of using only the particle to couple the light to air, the material having an emissive state is also used to enhance the efficiency of the light outcoupling. The material having an emissive state absorbs energy from the plasmon modes and converts it to light. The percentage of energy in the plasmon mode that goes to the emissive state may be less than 25%, less than 50%, or less than 75%. The percentage of energy in the plasmon mode that goes to the nanoparticles may be less than 25%, less than 50%, or less than 75%. The material having an emissive state being located outside the OLED stack can outcouple the converted light to air efficiently, thereby increasing the efficiency of the light outcoupling. Additionally, the material having an emissive state allows conversion of plasmonic energy within the multipolar LSPR modes of the particles to a dipolar emission, enhancing the outcoupling efficiency and increasing device brightness. In an embodiment, the device may have increased brightness which is due to an increase in the number of photons emitted. In an embodiment, this increased brightness may lead to reduced power consumption as compared to the power consumption of the device when it produced the original brightness before the increased brightness resulting from the new device design.

In typical plasmonic OLED devices, not all of the plasmon energy is outcoupled by the nanoparticles where the rest of the energy is dissipated as heat in the system. There are several loss pathways that can be avoided by introducing an emissive state into the outcoupling layer. First, the light outcoupling from the nanoparticles depends on the induced LSPR modes of the particles. The dipolar LSPR modes are more efficient in outcoupling the light, while the multipolar LSPR modes create hot spot regions within the nanoparticles, for example, at the corners of the nanoparticle, confining the energy, which gets dissipated as heat. The emissive state dispersed near the hot spot regions, which is a region of the nanoparticle that has at least three times, at least four times, at least five times, at least ten times, at least twenty-five times, at least fifty times, or at least one hundred times the electric field intensity relative to the average electric field intensity of the nano particles, can absorb the energy within the plasmon modes and re-emit it as a photon. Due to the strong near field coupling to the LSPR mode, the quantum yield and radiative rate of the emissive state may be enhanced in those hot spot regions, leading to efficient conversion of plasmon to photon, thereby enhancing the device efficiency. In some other cases, the plasmonically excited emissive states in the hot spot regions may be coupled back to a dipolar LSPR mode of the nanoparticle, which subsequently gets outcoupled, thereby converting energy confined within the multipolar LSPR modes in the hot spot regions to an emissive dipolar mode. The other form of multipolar to dipolar emission can occur when the material having emissive states couples strongly with the LSPR modes in the hot spot regions, generating hybridized exciton-plasmon states which exhibit increased radiative rates enhancing the device efficiency. The strong emission coupling can occur for emissive states dispersed less than 5 nm, or more preferably less than 2 nm from the surface of the metal nanoparticle and/or from the hot spot region of the metal nanoparticles.

A second source of loss is from the dielectric medium between the enhancement layer and the nanoparticles, where the plasmonic coupling creates strong electric field confinement. The field enhancement induced by the surface plasmon may be defined as a ratio of electric field components of the light at any emission wavelength with and without the metal structures. Using the material having an emissive state in the outcoupling structure, the nanoparticles can convert the energy in the waveguide mode to light instead of having it wasted as heat, effectively enhancing the device EQE.

The material having an emissive state can include one or more types of luminescent materials such as fluorophores, quantum dots, semiconducting rods, nano diamonds, transition metal dichalcogenides (TMDs), graphene oxide, carbon nanotubes, and/or the like. In some embodiments, the material having an emissive state will be excited by the surface plasmon modes generated by the coupling of energy to the second electrode, or enhancement layer where applicable. In other embodiments, the electroluminescence (EL) from the device provides the excitation energy for the material having an emissive state and the emission control may be achieved by means of optical coupling to the LSPR of the metal nanoparticles (NPs) in the outcoupling layer. In an embodiment, the emission control includes, but is not limited to, emission intensity, spectral width, peak emission wavelength, angular emission profile, and/or the like. In other embodiments, the material having an emissive state may emit light when excited by the strong field gradient generated by the surface plasmon model such as provided by the enhancement layer. In some embodiments, when the dominant mode of light emission is through the material having an emissive state, more than 20%, 30%, 40%, 50%, 60%, 70%, 80%, or 90% of the light energy will be outcoupled through the material having an emissive state, and this could approach 100%. In other embodiments, the material having an emissive state provides an additional pathway for light outcoupling from plasmonic OLEDs, enhancing the EQE, particularly at wavelength regions where the light outcoupling using the metal nanoparticles are less efficient. Since the material having an emissive state is located outside the OLED stack, and may be dispersed within a low index medium, loss due to waveguiding will be minimal.

In some embodiments, a material having an emissive state with a lower Stokes shift will be used to maximize the spectral overlap with the emissive material spectrum in the emissive layer (EML). A lower Stokes shift may be less than 50 nm, less than 20 nm, less than 10 nm, and/or the like. In other embodiments, a material having an emissive state with a large Stokes shift will be used to minimize the spectral overlap with the emission spectrum of the EML. In some embodiments, a large Stokes shift may be greater than 50 nm, greater than 75 nm, or greater than 100 nm. The emissive layer may have a first emissive spectrum range and the material having an emissive state may have a second emissive spectrum range. The amount of spectral overlap of the first emissive spectrum range and the second emissive spectrum range can modify an output characteristic of the device, for example, a color that is output, a saturation of the color that is output, a number of colors that are output, and/or the like. The amount of overlap between the emissive spectrum of the emissive layer and the emissive spectrum of the material having an emissive state may be described in nm ranges, in percentages, or a combination of nm ranges and percentages. For example, the emissive layer may have an emissive spectrum of 500-520 nm and the material having an emissive state may have an emissive spectrum that overlaps at least 50% of the emissive layer emissive spectrum. It should be noted that the material having an emissive state may have an associated color emissive spectrum. Thus, different materials having an emissive state may be utilized, with each having an associated color emissive spectra to get different color emitters, for example, red, blue, green, and/or the like. Accordingly, the outcoupling layer may include multiple or a plurality of materials having an emissive state, with each of the plurality of materials having an emissive state having a corresponding emission spectrum for the desired emission color.

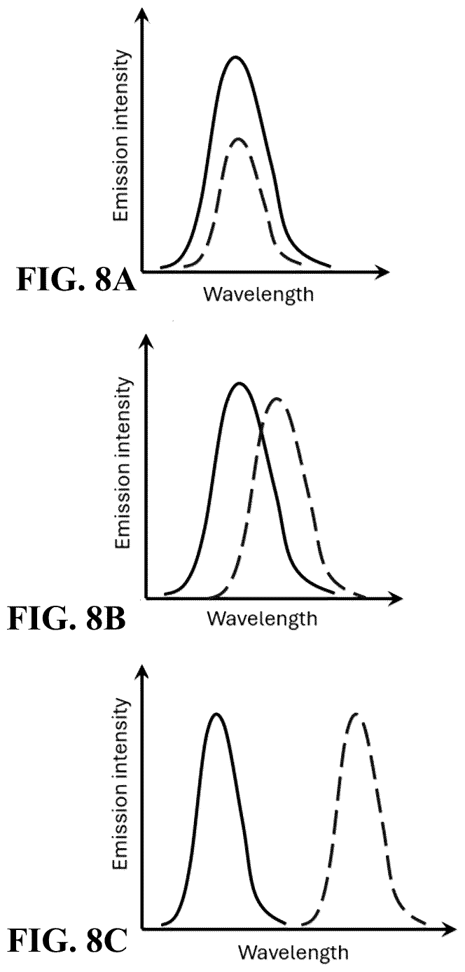

Both the first emissive range and the second emissive range may have peak spectral emission values. Inn an embodiment, the emissive range may have a single peak maximum emission wavelength. In an embodiment, the emissive range may have multiple peaks, that each have local maximum emission wavelengths. Additionally, the emissive ranges have other values that are not associated with the peak value, but that are adjacent to the peak value, which is considered to be the entire emission spectra. Embodiments of the present invention recognize the emissive state, emissive material, and/or emissive layer comprising the emissive material may each individually have a peak emission spectral emission value and may each individually have an entire emission spectra. For example, as illustrated in FIGS. 8A-8C, the emission spectra of a material with an emissive state is shown by a solid line and the emission spectra of the emissive material and/or emissive layer comprising the emissive material is shown by a dashed line. While graphs “a”, “b”, and “c” show the emissive material and/or emissive layer comprising the emissive material, in some cases, having a lower intensity emission spectrum than the emission spectrum of the emissive state, embodiments of the present invention recognize that the emission spectrum of the emissive state may have a higher intensity emission spectrum than the intensity of the emission spectrum of the emissive material and/or emissive layer comprising the emissive material over some and/or all ranges of emission spectra. All of the values plotted in a line make up the emissive spectra or emissive range of the emissive state, emissive material and/or emissive layer comprising the emissive material. Thus, a spectral overlap refers to how much of the first emissive range and the second emissive range overlap. In other words, an amount of spectral overlap identifies the emission wavelengths that are shared between or that occur within the first emissive range and the second emissive range.

An overlap may be no overlap at all, where no values of the first emissive range and the second emissive range overlap and the ranges may even have a difference between them, meaning they are not even adjacent to each other. Here, graph “c” shows an emissive spectra of an emissive material and/or emissive layer comprising an emissive material having no overlap with the emission spectrum of the emissive state. In other words, the emissive spectra of the material with an emissive state does not have any similar emissive spectra to the emissive spectra of the emitter material and/or emissive layer comprising the emissive material.

An overlap may be a partial overlap, where some of the values of the first emissive range overlap with values of the second emissive range. Here, graph “b” shows an emissive spectra of an emissive material and/or emissive layer comprising an emissive material partially overlapping the emission spectrum of the emissive state. In other words, the emissive spectra of the material with an emissive state may have some similarities, or overlap, with the emissive spectra of the emitter material and/or emissive layer comprising the emissive material. In alternative embodiment, the emissive spectra of the emissive material and/or emissive layer comprising the emissive material may have some similarities, or overlap, with the emissive spectra of the emissive spectra of the material with an emissive state. A partial overlap can cause a shift in the emissive spectrum emitted from the device. For example, the emissive spectrum of the device can be blue or red shifted utilizing a partial overlap between the first emissive range and the second emissive range. In other words, the emissive spectrum of the material having an emissive state is modified relative to the outcoupling to tune the output spectrum. If the emissive spectrum of the material having an emissive state is overlapped with the emissive spectrum at a tail or end of the emissive spectrum of the emissive layer, the emissive spectrum of the device can be red or blue shifted. For example, the emissive layer may emit at 500-520 nm and the material having an emissive state may emit at 490-510 nm, thus having an overlap at 500-510 nm. This causes a blue shift in the emissive spectrum from the device. As another example, the emissive layer may emit at 500-520 nm and the material having an emissive state may emit at 510-530 nm, thus having an overlap at 510-520 nm. This causes a red shift in the emissive spectrum from the device.

In some embodiments, the broadness or narrowness of the light emission from the device depends on the relative emission intensity of the material having an emissive state. In other words, if the material having an emissive state provides a lower percent (e.g., less than 25%, less than 20%, less than 10%, etc.) of the total light emission (i.e., the intensity of the emission of the emissive state relative to the emission from the emissive material and/or emissive layer comprising the emissive material) of the device, then a broadness or narrowness of the material having an emissive state does not affect the overall emissive intensity of the device as much. On the other hand, if the material having an emissive state provides a high percent (e.g., greater than 25%, greater than 40%, greater than 50%, greater than 60%, greater than 70%, greater than 80%, greater than 90%, etc.) of the total light emission of the device, then a broadness or narrowness of the material having an emissive state does affect the overall emissive intensity of the device. For example, if the material having an emissive state has a broad emissive spectrum, but the material having an emissive state only provides 10% of the total light emission of the device, then the broad emissive spectrum has little effect on the overall light emission of the device. As another example, if the material having an emissive state has a broad emissive spectrum and the material having an emissive state provides 50% of the total light emission of the device, then the broad emissive spectrum provides some effect on the overall light emission of the device. As a final example, if the material having an emissive state has a broad spectrum and the material having an emissive state provides 90% of the total light emission of the device, then the broad emissive spectrum has a large effect on the overall light emission of the device. The same examples hold true for a narrow emission spectrum of the material having an emissive state.

The overlap may also be a full overlap. In a full overlap, the peak of both the first emissive range and the second emissive range may match. However, even in a full overlap, not all of the values within the first emissive range and the second emissive range may be identical. In other words, while the peak values match, one of the emissive ranges may be narrower or wider as compared to the other of the emissive ranges. Here, graph “a” shows an emissive spectra of an emissive material and/or emissive layer comprising the emissive material fully overlapping the emission spectrum of the emissive state. In other words, the material having an emissive state and emissive material and/or emissive layer comprising the emissive material have the same peak emission, and a broader emission spectra for the emitter material and/or emissive layer comprising the emissive material. In an alternative embodiment, the emission spectra of the emissive state may have a broader emission spectra compared to the emitter material and/or emissive layer comprising the emissive material. Since the emissive ranges may include many different values, for identifying overlaps the ranges may be truncated at different points, for example, full width half max (FWHM) or full width quarter max (FWQM). These points refer to the values that fall at a specific point on the emissive range. The peak value is the wavelength value with the maximum spectral power value. Thus, half max refers to the wavelength value(s) within the emissive range that have half of the maximum spectral power value. Similarly, quarter max refers to the wavelength value(s) within the emissive range that have a quarter of the maximum spectral power value. Generally, there will be two values that fall at the specific point, either half max or quarter max, one on either side of the peak value. The difference between these two values makes up the full emissive range at full width half max or full width quarter max, depending on which value point is being utilized. The characteristic can be controlled by controlling a width of the first emissive range as compared to a width of the second emissive range. If the FWHM (or FWQM) of the second emissive range (the emissive range corresponding to the material having an emissive state) is less than the FWHM (or FWQM) of the first emissive range (the emissive range corresponding to the emissive layer) the saturation of the emission can be controlled. In other words, if the emissive spectrum of the material having an emissive state is narrower than the outcoupling spectra, or emissive spectrum of the emissive layer, the emissive spectrum from the device will be more saturated. For example, the emissive layer may emit at 500-520 nm and the material having an emissive state may emit at 505-515 nm, thus creating a more saturated color emission from the device.

In an embodiment, the emissive spectrum of the light output by the nanoparticle of the device may partially or fully overlap with the emission spectrum of the material having an emissive state located outside the OLED stack and within the outcoupling layer. Here, the emission spectrum of the device is primarily driven by the partial or full overlap of the emission spectrum of the emissive material and/or emissive layer comprising the emissive material and the outcoupling resonance of the nanoparticles within the outcoupling layer, which leads to an emission spectrum of the device with a first emissive range. Additionally, the material having an emissive state located in the outcoupling layer may have a second emissive range. Here, the device as a whole will have increased emission intensity, within an emissive spectrum that is an overlap between the first emissive range and the second emissive range.

If the FWHM (or FWQM) of the second emissive range (the emissive range corresponding to the material having an emissive state) is greater than the FWHM (or FWQM) of the first emissive range (the emissive range corresponding to the emissive layer) the number of colors can be controlled. In other words, if the emissive spectrum range of the material having an emissive state is greater than the spectral range for the light outcoupled by the nanoparticles (i.e., in other words, all of the spectral range for the light outcoupled by the nanoparticles is within the emissive spectrum range of the material having an emissive state), or the emissive spectrum range of the material having an emissive state has minimal or no overlap with the outcoupling spectra of the nanoparticles, the emissive spectrum from the device will be wider, thereby allowing for more colors within the emission. For example, to get closer to white, the emissive spectrum of the material having an emissive state may be wider than the emissive spectrum of the emissive layer. For example, the emissive layer may emit at 500-510 nm and the material having an emissive state may emit at 495-515 nm, thus providing a wider range of emissive spectrum from the device.

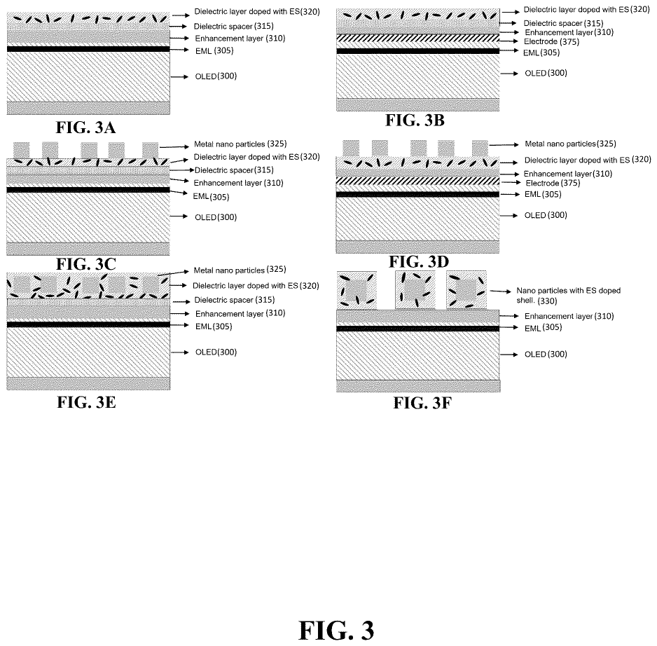

FIG. 3a-FIG. 3f show schematics of various plasmonic OLED designs utilizing an outcoupling layer including a material having an emissive state above an enhancement layer 310 for light outcoupling. Each device includes an OLED stack 300, an emissive layer 305, and enhancement layer 310. In some embodiments, the second electrode may be the enhancement layer 310, for example, as illustrated in FIG. 3a, FIG. 3c, FIG. 3e, and FIG. 3f. In other words, in these devices the second electrode and enhancement layer 310 are the same layer. In some embodiments, to enable the excitation of surface plasmon resonance modes, the emissive layer 305 may be disposed closer to the second electrode as compared to the first electrode. In some embodiments, the second electrode (or enhancement layer 310) may be any plasmonic material. The plasmonic material may be a metal, for example, a thin metallic layer of gold, silver, aluminum, and/or the like. The thickness of this thin metallic layer may be less than 20 nm, less than 30 nm, less than 50 nm, less than 100 nm, or, preferably, 30 nm±5 nm or 40 nm±5 nm.

In some embodiments, the device includes an enhancement layer 310 in addition to a second electrode. In the case that both an enhancement layer 310 and a second electrode 375 are included, the enhancement layer 310 could be disposed over the second electrode 375, the enhancement layer 310 may be disposed over the emissive layer 305 and the second electrode 375 is disposed over the enhancement layer 310, and/or the like. In some embodiments, to enable the excitation of surface plasmon resonance modes, the emissive layer 305 may be disposed closer to the enhancement layer 310 as compared to the first electrode. The distance between the top of the emissive layer 305 and the bottom of the enhancement layer 310 may be less than 50 nm, less than 30 nm, or less than 20 nm. This may assist in increasing plasmon generation in the enhancement layer 310. When a separate second electrode 375 and enhancement layer 310 are included, the second electrode 375 may be an optically transparent material. Materials may include, but are not limited to, indium tin oxide, fluorine doped tin oxide, indium doped zinc oxide, aluminum zinc oxide, indium-doped cadmium oxide, barium stannate, carbon nanotubes, graphene, multilayer graphene, single layer graphene, graphene oxide, metallic nanoparticles, nanowire impregnated materials, polyacetylene, polypyrrole, polyindole, polyaniline, Poly(p-phenylene vinylene), poly(3-alkylthiophenes), (poly(3,4-ethylenedioxythiophene)), strontium niobium oxide, and/or the like. In an embodiment, where the device includes a first electrode, second electrode, and enhancement layer, the separate second electrode 375 may have a thickness less than 20 nm, less than 50 nm, or, preferably, 20 nm±5 nm. The separate enhancement layer 310 may be any plasmonic material. The plasmonic material may be a metal, for example, a thin metallic layer of gold, silver, aluminum, and/or the like. The thickness of this thin metallic layer may be less than 20 nm, less than 30 nm, less than 50 nm, less than 100 nm, or, preferably, 30 nm±5 nm.

Devices having a separate enhancement layer 310 and second electrode 375 are illustrated in FIG. 3b and FIG. 3d as examples. In these examples, the second electrode 375 is deposited above the emissive layer 305 and the enhancement layer 310 is deposited above the second electrode 375. However, as previously mentioned, these are not the only configurations. In some embodiments, the outcoupling layer may be a dielectric layer doped with the material having an emissive state 320, for example, as illustrated in FIG. 3a and FIG. 3b. The outcoupling layer may be deposited above the enhancement layer 310. The entirety of the outcoupling layer may be the material having an emissive state. In other words, the material having an emissive state may be 100% of the outcoupling layer. In an alternative embodiment, the outcoupling layer is composed of the material having an emissive state and the material having an emissive state may be a specific volume fraction doped into a dielectric medium. The dielectric medium may have a refractive index of less than 2, less than 1.75, or, preferably, less than 1.5. The material having an emissive state may have a specific volume of the dielectric material and the material having an emissive state is less than 25%, less than 15%, less than 10%, less than 5%, less than 3%, less than 1%, less than 0.5%, or less than 0.1% of the combined volume of the emissive state and the dielectric material. In other words, the material having an emissive state doping may be less than 25%, 15%, 10%, 5%, 3%, 1%, 0.5%, 0.1% of the specific volume of the material having an emissive state and the dielectric medium combined.

Materials having an emissive state may include, but are not limited to, semiconducting quantum dots such as Cadmium selenide, Cadmium sulfide, Cadmium telluride, core shell cadmium selenide/zinc sulfide, rod shaped Cadmium selenide particles, lead sulfide, lead telluride, lead selenide, gallium arsenic (GaAs), gallium nitrides (GaN), lanthanide doped up conversion NPs, perovskite NPs, non-Cd-based QDs such as Indium Phosphide (InP) QDs, Copper Indium Sulfide (CuInS₂)/Zinc Sulfide (ZnS) Core/Shell QDs that are biocompatible, non-toxic and environmentally friendly, Organic Quantum Dots (Carbon Dots, Graphene QDs), ZnSeTe quantum dots, ZnSeTeS quantum dots, core shell ZnSeTeS/ZnSe/ZnS quantum dots, Silicon quantum dots, Nickel Sulfide-Zinc Sulfide (NiS—ZnS) Quantum Dots, Copper Indium Sulfide (CIS) quantum dots, core shell CIS/ZnS quantum dots, graphene oxide, carbon nanotube Multi-resonance thermally activated delayed fluorescence (MR-TADF) emitters, Perylene, Boron di-pyrromethene, Rhodamine, Fluorescein, Coumarins, -BODIPY dyes, Cyanines, Fluorescein isothiocyanate, Calcein, Ethidiumbromide, Phycoerythrin, Carboxynaphthofluorescein, Hexachlorofluorescein, Tetramethylrhodamine, henylethynylpyrene, phosphorescent dyes, MoSe₂, MoS₂, phosphorescent emitters, fluorescent emitters, delayed fluorescent emitters, doublet emitters, inverted singlet-triplet gap materials, emissive metal nanoparticles, compounds comprising lanthanide, conjugated fluorescent polymers such as -Polyfluorenes (PFO, F8BT), -Polythiophenes, -Poly(p-phenylene vinylene) (PPV), fluorescent dye functionalized polymers Polyethylene glycol (PEG) or polyvinyl alcohol (PVA) with fluorescein or rhodamine, -Polystyrene beads with embedded dyes, -Tetraphenylethylene (TPE)-based polymers, Silole derivatives and/or the like. The dielectric medium for dispersing the material having an emissive state may be formed using polymeric materials such as polystyrene, Polymethyl methacrylate, Poly vinyl pyridine, and/or the like. In some embodiments, the material having an emissive state will be embedded in porous materials formed using metal organic framework (MOF) or covalent organic framework (COF). The material having an emissive state may be infiltrated into the pores through solvent casting or may be deposited during the synthesis process. In some embodiments the material having emissive state may be part of the porous materials, for example the MOF, COF, etc. may comprise the material having an emissive state. Owing to the increase in the non-radiative process, the light outcoupling efficiency of the emissive states may decrease with an increase in device temperature. In an embodiment, with the device operating at room temperature or slightly above or below, the emissive state will function at room temperature. As used herein, room temperature is approximately 22° C. (e.g., 22° C.±1° C.). In an alternative embodiment, the device, and therefore the emissive state may function at increased and/or decreased temperatures (e.g., 10° C., 20° C., 30° C., 40° C., or 50° C. above or below room temperature).

In some embodiments, and as illustrated in FIGS. 3a, 3b, 3c, and 3e, to minimize the reabsorption of the emitted photons by the surface plasmon resonance (SPR) mode of the second electrode, a dielectric layer or dielectric spacer layer 315, may be deposited on the top surface of the enhancement layer 310 and the material having an emissive state will be deposited above this dielectric layer or dielectric spacer layer 315. The thickness of this dielectric layer or dielectric spacer layer 315 may be at least 5 nm, at least 10 nm, at least 25 nm, or less than 50 nm. In some embodiments, to reduce back coupling of emission to the SPR modes of the enhancement layer 310, the material having an emissive state may have a transition dipole aligned in plane to the enhancement layer 310. In other words, the transition dipole may be aligned in a plane that is parallel to a plane of the enhancement layer 310. In an embodiment, the material having an emissive state may have a low vertical dipole ratio (VDR), for example, less than 0.2, less than 0.1, less than 0.05, or less than 0.01.

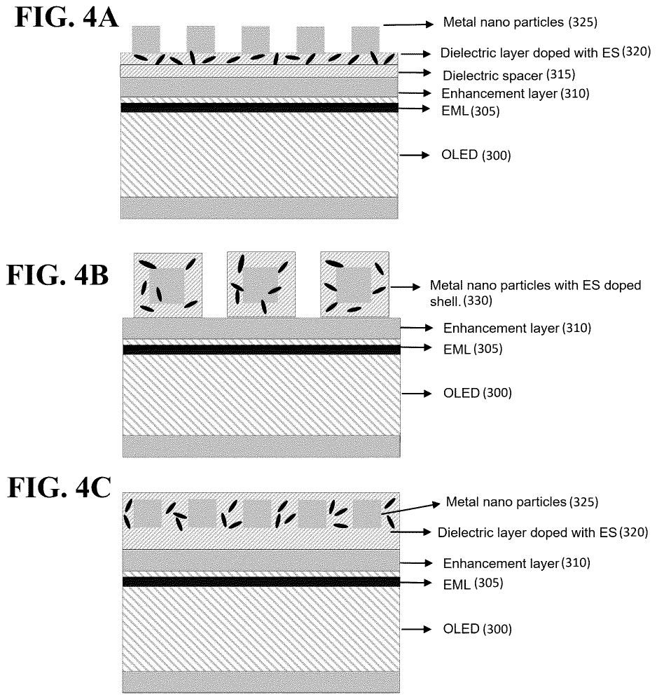

In some embodiments, the outcoupling layer may include multiple layers. For example, in some embodiments, the outcoupling layer additionally includes nanoparticles, for example, as illustrated in FIGS. 3c, 3d, 3e, and 3f. The nanoparticles may be metal nanoparticles 325, dielectric nanoparticles 355, a combination thereof, and/or the like. The nanoparticles may be different shapes, for example, a sphere, a cube, a square prism, a cylinder, a rectangular prism, a rod, a spheroid, an irregular shape, and/or the like. The material having an emissive state may be doped into the dielectric spacer layer 315 and the nanoparticles may be deposited above the dielectric spacer layer 315, for example, as illustrated in FIG. 3c, FIG. 3d, and FIG. 4a to form a nanoparticle based outcoupling structure, enabling light outcoupling through the conversion of plasmonic energy to light. In other words, the nanoparticles (325/355) may be disposed over the material having an emissive state. The thickness of the dielectric spacer layer 315 layer doped with the material having an emissive state may be less than 50 nm, less than 30 nm, or, preferably, less than 20 nm. The nanoparticles may be metal nanoparticles 325 and may be of a suitable size that may be based upon a color to be outcoupled by the nanoparticles. The sizing of the nanoparticles controls the sizing of the wavelength of light outcoupled by the nanoparticles.

In some embodiments, the material having an emissive state may be around at least a portion of the nanoparticles. For example, the nanoparticles may be disposed within a dielectric medium, for example, as illustrated in FIG. 3e and FIG. 4c. In FIG. 3e, the dielectric medium is doped with the material having an emissive state. In this example, the nanoparticles are deposited on top of the dielectric spacer layer 315 and the dielectric material being doped with the material having an emissive state is dispersed in the regions between the nanoparticles and into the dielectric spacer layer 315, thereby resulting in the material having an emissive state being below, above, and between the nanoparticles. In an embodiment, the specific location of the material having an emissive state may not be important, as long as the material having an emissive state increases the dipolar emission of the device. In an embodiment, it may be preferred to have the material having an emissive state located closer to the hot spot regions as further described herein (e.g., near sharp corners of nanoparticles and below the nanoparticles). In FIG. 4c, the dielectric medium is doped with the material having an emissive state. In this example, the nanoparticles are deposited on top of the dielectric spacer layer 315 medium and the dielectric material being doped with the material having an emissive state is dispersed in the regions between the nanoparticles, thereby resulting in the material having an emissive state being between the nanoparticles. Accordingly, the material having an emissive state may be on top of the nanoparticle, on the bottom of the nanoparticle, on a side of the nanoparticle (or between nanoparticles), a combination thereof, and/or the like.

In some embodiments, the nanoparticles may be coated with a thin layer of dielectric material that is doped with the material having an emissive state, for example, as illustrated in FIG. 3f and FIG. 4b. In other words, the nanoparticles may have a shell including a dielectric material doped with the material having an emissive state 330. The thickness of the shell may be less than 10 nm, less than 20 nm, less than 30 nm, less than 40 nm, or less than 100 nm. The refractive index of the material of the nanoparticle shell may have a refractive index less than 2.0, less than 1.5, or, more preferably, less than 1.25. In an embodiment, the shell thickness may be less than 500 nm, less than 250 nm, less than 100 nm, or more preferably, less than 50 nm. In an embodiment, an increase in the shell refractive may help with confining the plasmon energy. However, the light outcoupling efficiency may be affected with this increase. This shelled nanoparticle 330 may be deposited directly above the second electrode to form the outcoupling layer. The outcoupling layer may include a material located between the shelled nanoparticles. For example, the material may include air, a dielectric material, and/or the like. The nanoparticles deposited on the dielectric layer, regardless of whether the nanoparticles include shells, are within a dielectric material, or are deposited above the dielectric layer doped with the material having an emissive state 320, may have a random positional arrangement, as illustrated in FIG. 3c, FIG. 3d, FIG. 3e, and FIG. 3f, or may be periodic, as illustrated in FIG. 4.

In an embodiment, the shelled nanoparticle may be in the shape of a cube, as illustrated. Alternatively, the shelled nanoparticle may have sides that are a rectangle, square, triangle, or any other sided shape. In a preferred embodiment, the “bottom” side (the side closest or facing the enhancement layer) of the shell will have a first plane, and the first plane is preferably flat, and the “bottom” side (the side closest to the enhancement layer) of the nanoparticle will have a second plane, and the second plane is preferably flat. While the first plane and the second plane may not be in the same plane (although they may be in the same plane in some circumstances), the first plane and the second plan will be oriented relative to each other. In a preferred embodiment, the angle between the first plane and the second plane will be at or near 0. In an alternative embodiment, the angle between the first plane and the second plane is less than ±1 degrees, less than ±2 degrees, less than ±5 degrees, less than ±10 degrees, less than ±15 degrees, less than ±20 degrees, less than ±25 degrees, or less than ±30 degrees. In a preferred embodiment, the angle between the enhancement layer and the first plane is less than ±1 degrees, less than ±2 degrees, less than ±5 degrees, less than ±10 degrees, less than ±15 degrees, less than ±20 degrees, less than ±25 degrees, or less than ±30 degrees.

FIG. 4 illustrates additional embodiments where the nanoparticles are arranged in a periodic lattice with hexagonal, square, rectangular, rhombic lattice symmetries, a quasiperiodic array that shows a long-range positional order without any positional periodicity, and/or the like. The minimum center-to-center spacing between two nearby nanoparticles may be less than 100 nm, less than 300 nm, or less than 500 nm. In the embodiments where the nanoparticles have a periodic lattice, the periodic lattice introduces a collective mode for outcoupling where the electric field of the outcoupling mode is not localized to a single location, but rather extends over several particles within the periodic array. This collective mode, referred to as a lattice mode, can enhance light emission at specific angles when the scattering components in plane to the nanoparticle lattice constructively interfere. The material having an emissive state may be dispersed in the dielectric layer or in a dielectric shell around the nanoparticles or in the region between the nanoparticles. The light gets outcoupled through the lattice modes and the nanoparticle based outcoupling modes, which results in directional emission from the plasmonic OLEDs. Additionally, emission from the material having an emissive state may interact with the nanoparticle lattice mode resulting in any of the following, reduced angular dependence of emission, enhanced outcoupling efficiency, or modification of the spectral width of the outcoupling.

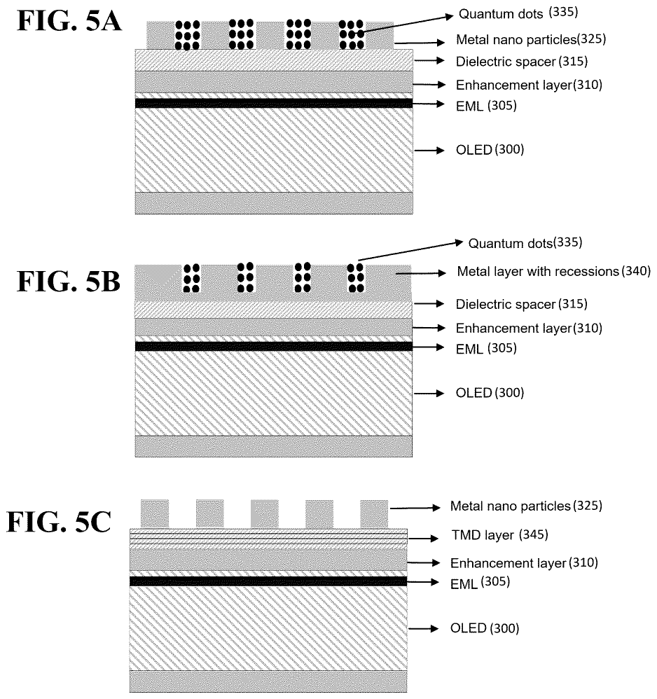

FIG. 5 illustrates additional embodiments that utilize metal nanoparticles 325. FIG. 5a illustrates the metal nanoparticles 325 being deposited on the dielectric spacer layer 315, as illustrated in FIG. 3 and FIG. 4. However, FIG. 5a illustrates the material having an emissive state as quantum dots 335 and being deposited in the regions between the metal nanoparticles 325. The outcoupling layer may also include a metal layer having nanoparticles included as a single continuous layer 340, for example, as shown in FIG. 5b. In other words, a single continuous metal layer 340 with periodic recessions is used for light outcoupling and is deposited above the dielectric spacer layer 315 layer or second electrode. The material having an emissive state is deposited within the recessions. In the example of FIG. 5b, the material having an emissive state are quantum dots 335, but other materials having an emissive state can be utilized, for example, dielectric material doped with the material having an emissive state, materials having an emissive state having a different shape, and/or any of the other materials having an emissive state as discussed further herein.

The material with an emissive state can be deposited by means of solvent casting, the Langmuir Blodget method, spin casting, dip coating, spray coating, inkjet printing, thermal evaporation, e-beam, sputtering, ALD, CVD, pulsed laser deposition, and/or the like. These deposition methods can be used to create multilayer quantum dots, or other material having an emissive state, within the metal recessions or between the nanoparticles in the outcoupling layer. The emission from the quantum dots optically coupled to the LSPR modes of the metal nanoparticles 325 can result in enhanced device EQE. Additionally, the emission from the quantum dots 335, or other material having an emissive state, can couple to the lattice resonance modes, which can enhance the quantum dot, or other material having an emissive state, emission and lead to directional emission from the device. The minimize the effect of non-radiative energy transfer between the semiconducting quantum dots 335, or other material having an emissive state, and the metal surface, which can result in quenching of quantum dot luminescence, the quantum dots 335 may be coated with a dielectric layer or shell. The shell may have a thickness of at least 10 nm, at least 20 nm, or greater than 30 nm. In some embodiments, quantum dots 335 with core shell or gradient shell geometry may be used. In some other embodiments, and as illustrated in FIG. 5c, a stack of single layer or multilayer TMDs 345 will be deposited above the second electrode and the metal nanoparticles 325 will be deposited above this layer. The TMDs act as the dielectric layer for the nanoparticle based outcoupling, while the luminescence produced by the TMDs can enhance the light outcoupling.

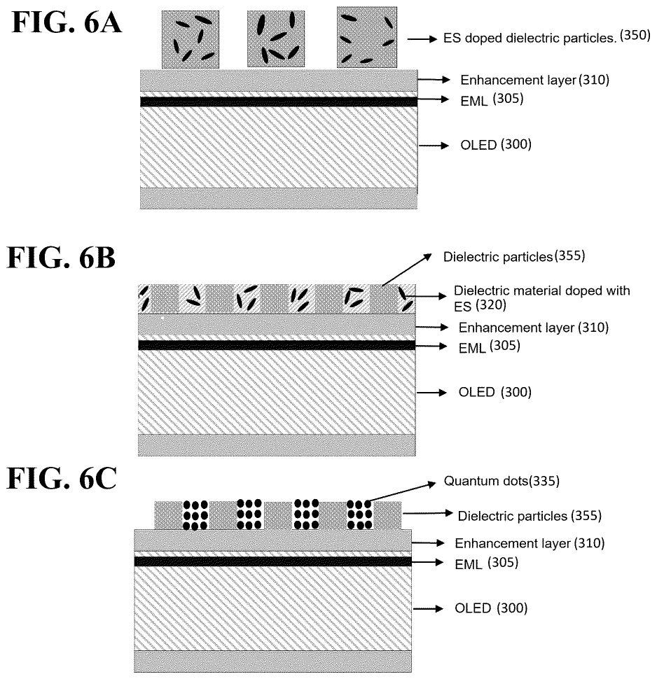

In some embodiments, and as previously discussed, the nanoparticles may be dielectric nanoparticles 355. FIG. 6 illustrates some configurations using dielectric nanoparticles 355, but it should be noted that unless specifically identified, the previously discussed configurations may utilize the dielectric nanoparticles. The dielectric nanoparticles may be high index dielectric nanoparticles that have a refractive index greater than 1.5, greater than 1.8, greater than 2.0, or greater than 2.5. The dielectric nanoparticles may be deposited directly on top of the second electrode. In other words, there may be a very thin dielectric spacer layer 315 layer or no dielectric spacer layer 315 layer. Thus, the dielectric spacer layer 315 layer may be less than 2 nm or 0 nm.

As illustrated in FIG. 6a, the dielectric particles may be doped with the material having an emissive state 350. The material having an emissive state may be doped into the particle in many ways including, but not limited to, during the synthesis, into a shell around the particles, intercalated into the particles, evaporated on to the particles, and/or the like. If placed next to a metallic second electrode, the nanoparticles outcouple the light through the metal dielectric plasmon modes and the material having the emissive state within the nanoparticles enable the outcoupling of waveguided energy within the nanoparticles. In other embodiments, dielectric material being doped with the material having an emissive state 320 will be deposited in the regions between the dielectric nanoparticles, for example, as illustrated in FIG. 6b. The dielectric nanoparticles 355 may be arranged having a random positional order or may have a periodic array. In other embodiments, the material having an emissive state will be deposited in the regions between the dielectric nanoparticles 355, for example, as illustrated in FIG. 6c, where the material having an emissive state is quantum dots 335. The emission from the material having an emissive state will be coupled to the plasmon mediated lattice resonance modes enhancing the radiative emission.

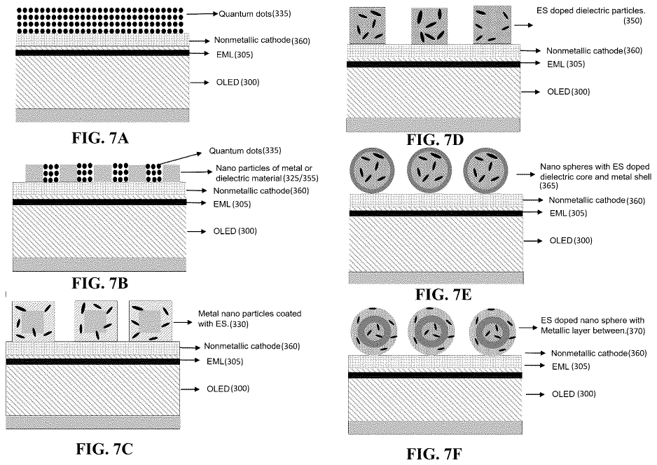

While plasmonic OLED devices have been discussed, the material having an emissive state can also be used in outcoupling structures for OLED devices. Example configurations of such devices are illustrated in FIG. 7. In these structures, OLED stacks are included 300. These OLEDs will have non-metallic second electrode 360. Here, an enhancement layer, as described above, is not required in the device. The non-metallic second electrode 360 may be made of a material including, but not limited to, indium tin oxide (ITO), fluorine doped tin oxide (FTO), indium doped zinc oxide (IZO), Aluminum Zinc Oxide (AZO), indium-doped cadmium oxide, strontium niobium oxide (SrNbO3), barium stannate, carbon nanotubes, graphene, multilayer graphene, single layer graphene, graphene oxide, metallic nanoparticle or nanowire impregnated materials, polyacetylene, polypyrrole, polyindole, polyaniline, Poly(p-phenylene vinylene), poly(3-alkylthiophenes), and (poly(3,4-ethylenedioxythiophene). Illustrated in FIG. 7a, a layer of the material having an emissive state will be deposited above the non-metallic second electrode 360. In this example, the material having an emissive state are quantum dots 335. The emission from the emissive layer 305 optically excites the material having an emissive state in the outcoupling layer. Additionally, the material having an emissive state deposited on the second electrode can convert the evanescent electromagnetic (EM) field components at the electrode surface to far field emission, which can enhance the light outcoupling efficiency. It should be noted, this embodiment described above may occur in a top emission device that emits light through a side opposite the substrate or a bottom emission device that emits light through the substrate the device is formed on. In an embodiment, the material having an emissive state can be used to enhance bottom emission, top emission, or microcavity OLED devices.

In embodiments without an enhancement layer (e.g., a nonmetallic electrode disposed under the outcoupling layer), the outcoupling layer may also include nanoparticles, which may be metal nanoparticles 325 or dielectric nanoparticles 355, for example, as illustrated in FIGS. 7b, 7c, 7d, 7e, and 7f. The nanoparticles may have spaces or regions between the nanoparticles. In some embodiments, the nanoparticles may be dispersed on the non-metallic second electrode 360 and the material having an emissive state will be dispersed between the nanoparticles to enhance light outcoupling, as illustrated in FIG. 7b. The material used for the second electrode may include, but are not limited to, indium tin oxide, fluorine doped tin oxide, indium doped zinc oxide, Aluminum Zinc Oxide, indium-doped cadmium oxide, barium stannate, carbon nanotubes, graphene, multilayer graphene, single layer graphene, graphene oxide, metallic nanoparticle or nanowire impregnated materials, as well as conductive polymers such as polyacetylene, polypyrrole, polyindole, polyaniline, Poly(p-phenylene vinylene), and/or poly(3-alkylthiophenes), (poly(3,4-ethylenedioxythiophene)). The emission from the emissive layer 305 couples to the nanoparticles through the Mie resonances, enabling light outcoupling. The material having an emissive state dispersed between the nanoparticles converts the evanescent EM wave due to waveguiding within the nanoparticles and in the OLED stack to far field radiation. In an embodiment, the Mie resonance may enable enhanced light outcoupling from the device, increasing the device efficiency, also enabling control of the emission line width, peak emission wavelength, and emission range. To enable coupling of the emissions from the emissive layer 305 to the Mie scattering modes of the nanoparticles, the distance from the top of the emissive layer 305 to the bottom of the nanoparticle layer may be less than 50 nm, less than 100 nm, or less than 200 nm. The width of the emission line is determined by the Mie scattering mode of the particles to which the emissive state in the EML can couple, which depends on the particle size and refractive index of the material. Scattering from higher order Mie modes enables narrow emission line shape. However, the higher order Mie resonance modes result in a multipolar photonic mode within the particle, which is less efficient in light outcoupling. The nanoparticles may also be dielectric nanoparticles that are doped with the material having an emissive state 350, for example, as illustrated in FIG. 7d. The material having an emissive state within the dielectric nanoparticles enables outcoupling of multipolar photonic modes within the particles arising from the higher order Mie scattering resonances, enhancing the light outcoupling, while enabling saturated emission by narrowing emission line shape. The nanoparticles may have a random positional order, a periodic order, or a quasiperiodic order. The emission from the material having an emissive state dispersed between the nanoparticles can interact with the lattice mode, enabling control over emission line width, angular emission profile, and emission pattern.

In embodiment without an enhancement layer (e.g., a nonmetallic electrode disposed under the outcoupling layer), the material in the regions between the nanoparticles may be air. In some embodiments, the nanoparticles may be metal nanoparticles that are coated with the material having an emissive state 330 giving the nanoparticles a shell made of the material having an emissive state, for example, as illustrated in FIG. 7c. The nanoparticles outcouple the light through the LSPR and the material having an emissive state dispersed in between or on the nanoparticle surface can convert the energy confined in the multipolar lossy modes to light, enhancing the light outcoupling. Additionally, the strong near field interaction between the LSPR modes of the metal nanoparticles and emissive states may enhance the spontaneous radiative rate and quantum yield of the emissive state enhancing the light emission. In some embodiments, for emissive states dispersed less than 5 nm, or more preferably less than 2 nm from the surface of the metal nanoparticle or to the hot spot region, the strong coupling of emissive states with the LSPR modes of the metal nanoparticles may create new hybridized modes with modified spectral characteristics enabling increased light outcoupling and highly tunable spectral properties such as line shape, emission wavelength, and/or the like. The nanoparticles can be any shape, as previously mentioned, for example, spheres, cubes, square prisms, cylinders, rectangular prisms, rods, spheroids, an irregular shape, and/or the like, with the material having an emissive state dispersed into a shell around the nanoparticle.

FIGS. 7e and 7f illustrates the nanoparticles having a sphere shape. However, other shapes may be utilized. In FIG. 7e, the nano spheres have a dielectric core that is doped with the material having an emissive state 365. The nano spheres also include a metal shell around the core. The metal shell around the material having an emissive state can enhance the radiative rates of the material having an emissive state. The metal shell can also concentrate the light from the OLED by converting the evanescent modes that exist on the second electrode surface to localized plasmons, enabling conversion to photons by the material having an emissive state dispersed in the nanoparticle core. The nanoparticles may also be spheres that have multiple layers of metal and dielectric material doped with the material having an emissive state 370, as illustrated in FIG. 7f. In this example, the nanoparticles are a dielectric material doped with the material having an emissive state with a layer of metal located within the dielectric material doped with the material having an emissive state. Stated differently, in this example embodiment, the nanoparticle is a first layer of dielectric material doped with the material having an emissive state, a metallic layer surrounding the first layer, and then a second layer of dielectric material doped with the material having an emissive state.

Embodiments described herein may be found in devices that have pixels that include one or more sub-pixels. Embodiments described herein may be found in at least one of the one or more sub-pixels. In a first embodiment, at least one of the sub-pixels may be in a side-by-side (SBS) architecture. In a SBS architecture, at least one or more emissive layers of each sub-pixel in the pixel are different than another sub-pixel in the pixel. Generally, a “Red” sub-pixel will have a red emissive layer and the red emissive layer emits red light and the sub-pixel emits red light. In an embodiment, there may be no color filter or color altering layer in a SBS architecture, although this is not a requirement and a color filter or color altering layer may be used. In a second embodiment, at least one of the sub-pixels may be in a stacked architecture. In a stacked architecture, at least one or more emissive layer is shared between two or more sub-pixels in the pixel. Generally, this is used in a white plus color filter/color altering layer architecture, where the emissive layers in the pixel produce “white” light and different color filter/color altering layer arrangements are used for sub-pixels in the pixel to produce a desired color. For example, the stack could produce “white,” a first sub-pixel could have a red color filter/color altering layer, so the first sub-pixel would produce red light and a second sub-pixel could have a green color filter/color altering layer, so the second sub-pixel would produce green light. Any color filtering/altering may be used to produce any color light. Additionally, the stack does not necessarily need to produce a “white” light and can produce any color light. Devices may be made that are a mixture of both SBS and stack architecture to produce pixel/sub-pixel designs that includes some or all of the embodiments described. Embodiments of the present invention may be included in one or more of a SBS or stacked pixel/sub-pixel design.

Additionally, any of the devices herein may replace either the first electrode or the second electrode with a charge generation layer. Here, a second device (or more), similar or different to the devices to the first device and/or similar or different to devices described in embodiments herein, may be placed in series with the first device in order to form a tandem device. In a tandem device, the first device may have an anode or a cathode on a side of the first device farther from the second device, between the first and second device may be a charge generation layer which replaces the anode or cathode, and the second device may have either an anode or cathode (whichever was not found in the first device) on a side of the of the second device farther from the first device.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device, the device comprising:
a substrate;
a first electrode;
an emissive layer comprising an organic emissive material disposed over the first electrode;
a second electrode disposed over the emissive layer; and
an outcoupling layer disposed over the second electrode, wherein the outcoupling layer comprises a material having an emissive state.

2. The device of claim 1, wherein the material having an emissive state increases the number of photons emitted by the device relative to the device without the material having an emissive state.

3. The device of claim 1, further comprising an enhancement layer, comprising a plasmonic material exhibiting surface plasmon resonance that non-radiatively couples to the organic emissive material and transfers excited state energy from the organic emissive material to non-radiative mode of surface plasmon polaritons, disposed over the emissive layer opposite from the second electrode, wherein the enhancement layer is provided no more than a threshold distance away from the organic emissive material, wherein at least one of the following (i), (ii), and (iii) is true:
i) the first electrode is an enhancement layer;
ii) the second electrode is an enhancement layer; and
iii) further comprising an enhancement layer.

4-17. (canceled)

18. The device of claim 1, wherein the outcoupling layer comprises a dielectric material and wherein the dielectric material is doped with the material having an emissive state.

19. The device of claim 18, wherein the dielectric material has a refractive index selected from the group consisting of: less than 2, less than 1.75, and less than 1.5.

20. The device of claim 18, wherein the material having an emissive state is doped within the dielectric material at a volume selected from the group consisting of: less than 25%, less than 15%, less than 10%, less than 5%, less than 3%, less than 1%, less than 0.5%, and less than 0.1%.

21. The device of claim 1, wherein the outcoupling layer comprises a porous material and wherein the material having an emissive state is embedded in the porous material.

22. The device of claim 21, wherein the porous material comprises at least one of a metal organic framework and a covalent organic framework.

23-24. (canceled)

25. The device of claim 1, wherein the outcoupling layer comprises nanoparticles.

26. The device of claim 25, wherein the nanoparticles comprise dielectric nanoparticles.

27. The device of claim 26, wherein the dielectric nanoparticles are doped with the material having an emissive state.

28-34. (canceled)

35. The device of claim 25, wherein the material having an emissive state is around at least a portion of the nanoparticle.

36. The device of claim 35, wherein the at least a portion of the nanoparticle comprises at least one of: a top of the nanoparticle, a bottom of the nanoparticle, and a side of the nanoparticle.

27-62. (canceled)

63. The device of claim 1, wherein the material having an emissive state converts energy in multipolar localized surface plasmon resonance modes to dipolar emissive modes.

64. The device of claim 1, wherein the material having an emissive state is a luminescent material selected from the group consisting of: fluorophores, quantum dots, semiconducting rods, nano diamonds, and transition metal dichalcogenides.

65. The device of claim 1, wherein the material having an emissive state is a material selected from the group consisting of: cadmium selenide, cadmium sulfide, Cadmium telluride, core shell cadmium selenide/zinc sulfide, rod shaped Cadmium selenide particles, lead sulfide, lead telluride, lead selenide, gallium arsenic (GaAs), gallium nitrides (GaN), lanthanide doped up conversion NPs, perovskite NPs, Indium Phosphide (InP) quantum dots, Copper Indium Sulfide (CuInS₂)/Zinc Sulfide (ZnS) Core/Shell quantum dots that are biocompatible, organic quantum dots, carbon dots, graphene quantum dots, ZnSeTe quantum dots, ZnSeTeS quantum dots, core shell ZnSeTeS/ZnSe/ZnS quantum dots, Silicon quantum dots, Nickel Sulfide-Zinc Sulfide (NiS—ZnS) Quantum Dots, Copper Indium Sulfide (CIS) quantum dots, core shell CIS/ZnS quantum dots, graphene oxide, carbon nanotube Multi resonance thermally activated delayed fluorescence (MR-TADF) emitters, Perylene, Boron di-pyrromethene, Rhodamine, Fluorescein, Coumarins, -BODIPY dyes, Cyanines, Fluorescein isothiocyanate, Calcein, Ethidiumbromide, Phycoerythrin, Carboxynaphthofluorescein, Hexachlorofluorescein, Tetramethylrhodamine, henylethynylpyrene, phosphorescent dyes, MoSe₂, and MoS₂, phosphorescent emitters, fluorescent emitters, delayed fluorescent emitters, doublet emitters, inverted singlet-triplet gap materials, emissive metal nanoparticles, compounds comprising lanthanide, conjugated fluorescent polymers such as -Polyfluorenes (PFO, F8BT), -Polythiophenes, -Poly(p-phenylene vinylene) (PPV), fluorescent dye functionalized polymers Polyethylene glycol (PEG) or polyvinyl alcohol (PVA) with fluorescein or rhodamine, -Polystyrene beads with embedded dyes, -Tetraphenylethylene (TPE)-based polymers, Silole derivatives.

66. The device of claim 1, wherein the material having an emissive state comprises a material having an emissive state with a small Stokes shift as compared to the emissive layer, wherein a small Stokes shift is less than 50 nm, less than 20 nm, or less than 10 nm.

67-79. (canceled)

80. The device of claim 3, wherein the organic emissive material has a total non-radiative decay rate constant and a total radiative decay rate constant due to the presence of the enhancement layer, and the threshold distance is where the total non-radiative decay rate constant is equal to the total radiative decay rate constant.

81. The device of claim 3, wherein the organic emissive material has a total non-radiative decay rate constant
$${k}_{non - rad}^{0} ,$$
a total radiative decay rate constant
$${k}_{rad}^{0} ,$$
a total non-radiative decay rate constant due to the enhancement layer
$${k}_{non - rad}^{plasmon} ,$$
and a total radiative decay rate constant due to the enhancement layer
$${k}_{rad}^{plasmon} ;$$
and
wherein the threshold distance is a distance at which
$$\frac{{k}_{rad}^{plasmon}}{{k}_{non - rad}^{plasmon}} = \frac{{k}_{rad}^{0}}{{k}_{non - rad}^{0}} .$$

82-85. (canceled)

86. The device of claim 1, wherein the device is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign.
